(19) United States
(12) Patent Application Publication
(10) Pub. No.: US 2026/0178088 A1
(43) Pub. Date: Jun. 25, 2026

(54) INFORMATION HANDLING SYSTEM CABINET WITH AN OFFSET SUPPORT BRACKET

(71) Applicant: DELL PRODUCTS L.P., Round Rock, TX (US)

(72) Inventor: Yi-Hsuan Chen, Taoyuan City (TW)

(21) Appl. No.: 18/988,575

(22) Filed: Dec. 19, 2024

(51) Int. Cl. G06F 1/18; G06F 1/16

(52) U.S. Cl. CPC G06F 1/183; G06F 1/1601

(57) ABSTRACT

A cabinet for an information handling system is disclosed and includes a housing, a vertical adjustable mounting rail, a horizontal information handling system support rail, and an offset mounting bracket connecting the horizontal information handling system support rail to the vertical adjustable mounting rail. The offset mounting bracket provides an offset length to move the horizontal information handling system support rail a distance away from the vertical adjustable mounting rail equal to the offset length.

### FIELD OF THE DISCLOSURE

The present disclosure generally relates to information handling systems, and more particularly relates to an information handling system cabinet having an offset support bracket.

### BACKGROUND

As the value and use of information continues to increase, individuals and businesses seek additional ways to process and store information. One option is an information handling system. An information handling system generally processes, compiles, stores, or communicates information or data for business, personal, or other purposes. Technology and information handling needs and requirements can vary between different applications. Thus, information handling systems can also vary regarding what information is handled, how the information is handled, how much information is processed, stored, or communicated, and how quickly and efficiently the information can be processed, stored, or communicated. The variations in information handling systems allow information handling systems to be general or configured for a specific user or specific use such as financial transaction processing, airline reservations, enterprise data storage, or global communications. In addition, information handling systems can include a variety of hardware and software resources that can be configured to process, store, and communicate information and can include one or more computer systems, graphics interface systems, data storage systems, networking systems, and mobile communication systems. Information handling systems can also implement various virtualized architectures. Data and voice communications among information handling systems may be via networks that are wired, wireless, or some combination.

### SUMMARY

A cabinet for an information handling system is disclosed and includes a housing, a vertical adjustable mounting rail, a horizontal information handling system support rail, and an offset mounting bracket connecting the horizontal information handling system support rail to the vertical adjustable mounting rail. The offset mounting bracket provides an offset length to move the horizontal information handling system support rail a distance away from the vertical adjustable mounting rail equal to the offset length.

### BRIEF DESCRIPTION OF THE DRAWINGS

It will be appreciated that for simplicity and clarity of illustration, elements illustrated in the Figures are not necessarily drawn to scale. For example, the dimensions of some elements may be exaggerated relative to other elements. Embodiments incorporating teachings of the present disclosure are shown and described with respect to the drawings herein, in which:

FIG. 1 is a perspective view of a lower portion of a cabinet for information handling systems according to an embodiment of the present disclosure;

FIG. 2 is a detailed view of the cabinet for information handling systems according to an embodiment of the present disclosure taken at box 2 in FIG. 1 according to an embodiment of the present disclosure;

FIG. 3 is a perspective view of an offset bracket for an information handling system according to an embodiment of the present disclosure;

FIG. 4 is another perspective view of a lower portion of a cabinet for information handling systems according to an embodiment of the present disclosure;

FIG. 5 is a perspective view of another offset bracket for an information handling system according to an embodiment of the present disclosure;

FIG. 6 is an exploded, perspective view of the offset bracket of FIG. 5 according to an embodiment of the present disclosure; and

FIG. 7 is a block diagram of a general information handling system according to an embodiment of the present disclosure.

The use of the same reference symbols in different drawings indicates similar or identical items.

### DETAILED DESCRIPTION OF THE DRAWINGS

The following description in combination with the Figures is provided to assist in understanding the teachings disclosed herein. The description is focused on specific implementations and embodiments of the teachings and is provided to assist in describing the teachings. This focus should not be interpreted as a limitation on the scope or applicability of the teachings.

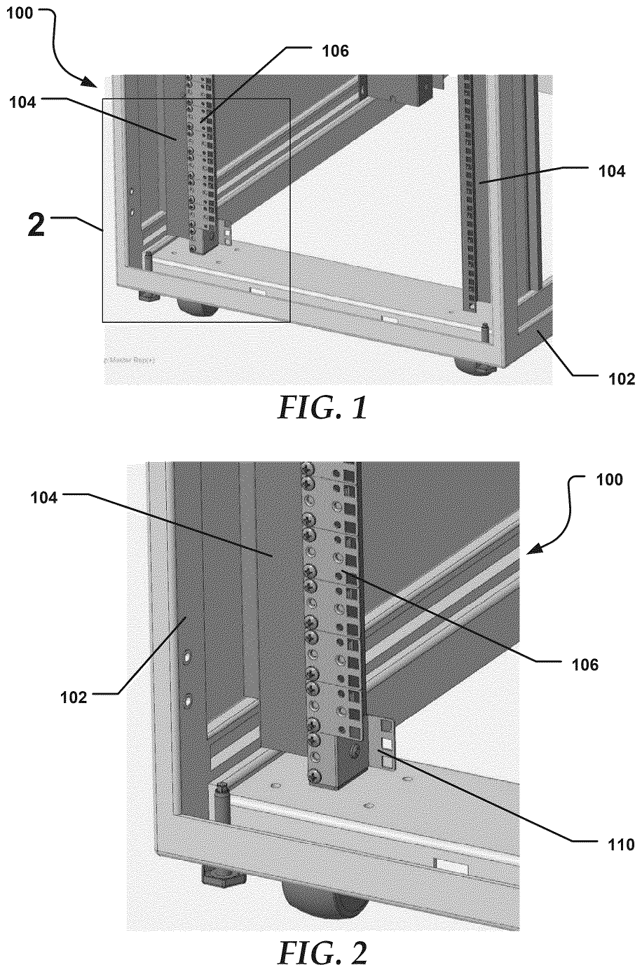

FIG. 1 illustrates a cabinet 100 in which one or more information handling systems may be installed. For purposes of this disclosure, an information handling system can include any instrumentality or aggregate of instrumentalities operable to compute, calculate, determine, classify, process, transmit, receive, retrieve, originate, switch, store, display, communicate, manifest, detect, record, reproduce, handle, or utilize any form of information, intelligence, or data for business, scientific, control, or other purposes. For example, an information handling system may be a personal computer (such as a desktop or laptop), tablet computer, mobile device (such as a personal digital assistant (PDA) or smart phone), server (such as a blade server or rack server), a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communicating with external devices as well as various input and output (I/O) devices, such as a keyboard, a mouse, touchscreen and/or a video display. The information handling system may also include one or more buses operable to transmit communications between the various hardware components.

FIG. 2 illustrates a portion of the cabinet 100 for information handling systems according to an embodiment of the present disclosure taken at box 2 in FIG. 1 according to an embodiment of the present disclosure. As shown in FIGS. 1 and 2, the cabinet 100 may include a housing 102 in which four vertical adjustable mounting rails 104 are disposed (e.g., two in the front and two spaced apart therefrom in the rear). One or more flat mounting brackets 106 may be affixed to, or otherwise disposed on, the vertical adjustable mounting rails 104. Each flat mounting bracket 106 is a rectilinear plate formed with one or cylindrical bores to allow the flat mounting bracket 106 to be mounted on, or otherwise attached to, a vertical adjustable mounting rail 104 via one or more fasteners and one or more square bores configured to receive complementary shaped cage nuts to which a horizontal information handling system support rail may be attached or otherwise affixed. As illustrated in FIG. 2, the cabinet 100 may include one or more offset mounting brackets 110 that may be affixed to, or otherwise disposed on, the vertical adjustable mounting rails 104. The offset mounting brackets 110 allow an information handling system to be shifted in a rearward direction to provide space forward of the information handling system for cables, etc.

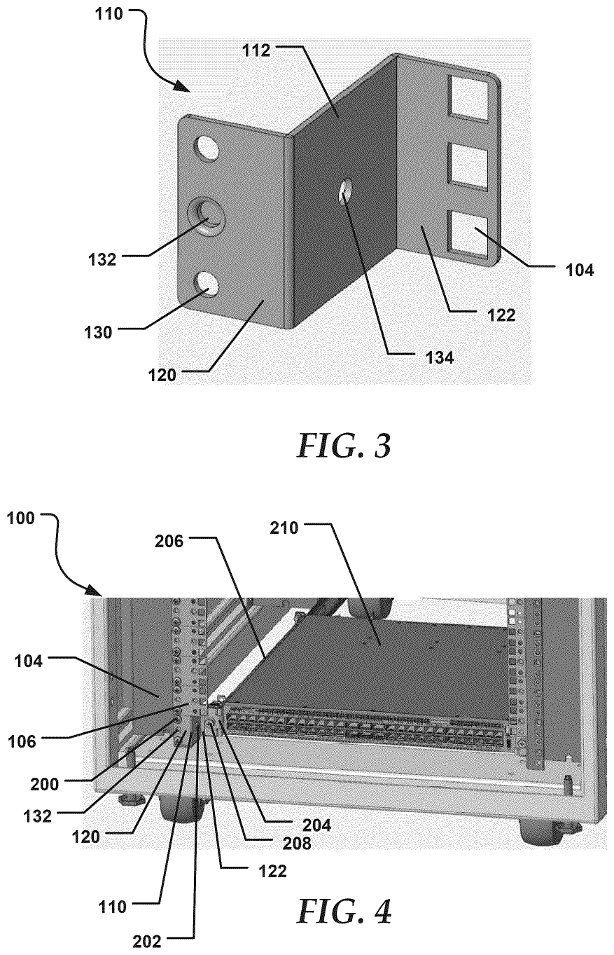

As shown in FIG. 3, the offset mounting bracket 110 is a one-piece, monolithic component that may be stamped from metal, such as steel. The offset mounting bracket 110 may include a central portion 112 that is a central plate. A first mounting tab 120 may extend from the central plate 114 in a first direction perpendicular to the central plate 114. Further, a second mounting tab 122 may extend from the central plate 112 in a second direction perpendicular to the central plate 112 opposite the first mounting tab 120. The first mounting tab 120 may include one or more circular bores 130 through which a fastener may extend to connect, or otherwise couple, the first mounting tab 120 to a vertical adjustable mounting rail, such as the vertical adjustable mounting rail 104 of FIG. 1. Further, the first mounting tab 120 may include a round indexing post 132 extending perpendicular from the mounting tab 120 toward the second mounting tab 122 that is configured to engage a complementary bore on the mounting rail 104. The central plate 112 may also include a bore 134 perpendicular to the bores 130 on the first mounting tab 120. The second mounting tab 122 may include one or more square bores 140 that are sized and shaped to receive complementary sized and shaped cage nuts therein to allow an information handling system support rail to be coupled, or otherwise affixed, thereto. Accordingly, the offset mounting bracket 110 is a one-piece bracket that provides a fixed offset length measured between the first mounting tab 120 and the second mounting tab 122.

As illustrated in FIG. 4, offset mounting brackets 110 may be installed on opposing vertical adjustable mounting rails 104 after removing the flat mounting brackets 106 by removing the fasteners 200 that hold them in place. Once the flat mounting brackets 106 are removed, the first mounting tab 120 of the offset mounting bracket 110 may be placed against the face of the vertical adjustable mounting rail 104 (the indexing post 132 will extend into and engage an empty fastener bore on the vertical adjustable mounting rail 104). Fasteners 200 may be inserted, or otherwise installed, through the bores 130 on the first mounting tab 120 and into threaded bores on the vertical adjustable mounting rail 104. The fasteners 200 are tightened to hold the offset mounting bracket 110 in place on the vertical adjustable mounting rail 104. Another fastener 202 may be inserted through the bore 134 in the central plate 112 and threadably engaged with a threaded hole on the vertical adjustable mounting rail 104.

A cage nut may be installed, or otherwise disposed, in one of the square bores 140 on the second mounting tab 122 and a clip 204 may be placed over an end of a horizontal information handling support rail 206 and a fastener 208 may be inserted therethrough and threadably engaged with the cage nut. An information handling system 210 may be installed on the horizontal information handling support rail 206. A similar arrangement may be assembled on the opposite vertical adjustable mounting rail 104 to support the opposite side of the information handling system 210. Accordingly, the information handling system 210 may be shifted rearward by the offset mounting bracket 110 by an offset length, L_{O}, that is equal to the length of the central plate 112 as measured between the first mounting tab 120 and the second mounting tab 122.

In a particular aspect, the offset mounting bracket 110 may have a width, W, and L_{O} may be greater than or equal to 1.0 W. Further, L_{O} may be greater than or equal to 1.25 W, such as greater than or equal to 1.5 W, greater than or equal to 1.75 W, greater than or equal to 2.0 W, greater than or equal to 2.25 W, greater than or equal to 2.5 W, greater than or equal to 2.75 W, or greater than or equal to 3.0 W. In another aspect, L_{O} may be less than or equal to 5.0 W, such as less than or equal to 4.75 W, less than or equal to 4.5 W, less than or equal to 4.25 W, less than or equal to 4.0 W, less than or equal to 3.75 W, less than or equal to 3.5 W, or less than or equal to 3.25 W. It is to be understood that L_{O} may be within a range between, and including, any of the minimum and maximum values of L_{O} disclosed herein.

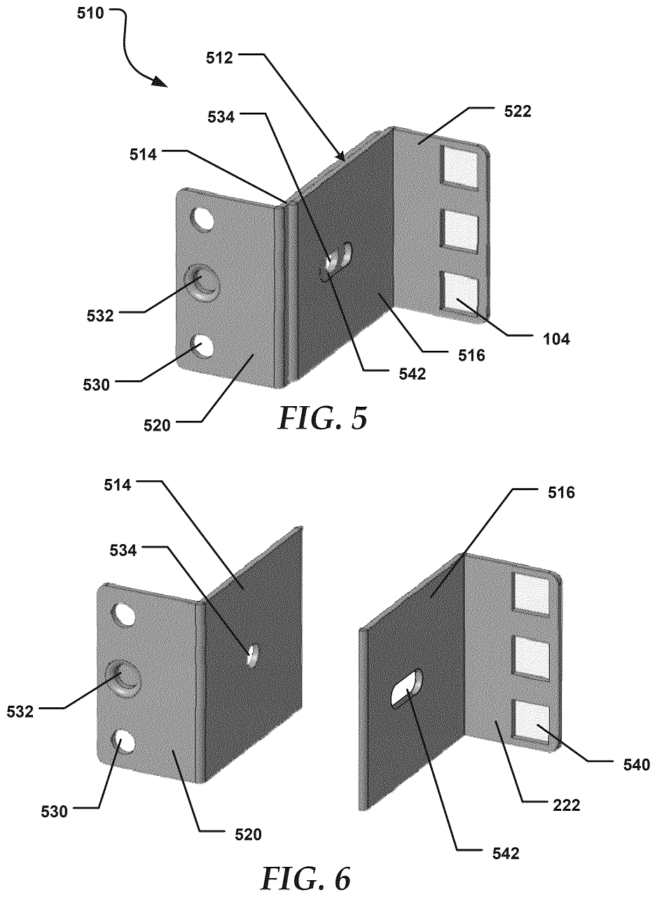

FIGS. 5 and 6 depict another embodiment of an offset mounting bracket 510 that may be affixed to, or otherwise mounted on, the mounting rails 104 in FIG. 1. The offset mounting bracket 510 is adjustable and may be used in lieu of the fixed offset mounting bracket 110 described above with respect to FIG. 2. As shown, the offset mounting bracket 510 may include a central portion 512 having a first central plate 514 and a second central plate 516 adjacent thereto. A first mounting tab 520 may extend from the first central plate 514 in a first direction perpendicular to the first central plate 514. Further, a second mounting tab 522 may extend from the second central plate 516 in a second direction perpendicular to the second central plate 516 opposite the first mounting tab 520. The first mounting tab 520 may include one or more circular bores 530 through which a fastener may extend to connect, or otherwise couple, the first mounting tab 120 to a mounting rail 104.

Further, the first mounting tab 520 may include a round indexing post 532 extending perpendicular from the mounting tab 520 toward the second mounting tab 522 that is configured to engage a complementary bore on the mounting rail 104. The first central plate 514 may also include a bore 534 perpendicular to the bores 530 on the first mounting tab 520. The second mounting tab 522 may include one or more square bores 540 that are sized and shaped to receive complementary sized and shaped cage nuts therein to allow an information handling system support rail to be coupled, or otherwise affixed, thereto.

The second central plate 516 may further include a slot 542 extending at least partially along a length, L, of the second central plate 516. The slot 542 may extend from a center of the second central plate 516 in a direction away from the second mounting tab 522, e.g., toward a front of the offset mounting bracket 510. Moreover, for example, the slot 542 have a slot length, L_{S}, and L_{S} may be greater than or equal to 0.1 L, such as greater than or equal to 0.15 L, greater than or equal to 0.2 L, greater than or equal to 0.25 L, or greater than or equal to 0.30 L. Further, L_{S} may be less than or equal to 0.45 L, such as less than or equal to 0.40 L, or less than 0.35 L. It is to be understood that L_{S} may be within a range between and including any of the minimum and maximum values of L_{S} described herein.

When assembled, the slot 542 on the second central plate 516 is aligned with the bore 534 on the first central plate 514 and the second central plate 516 may slide relative to the first central plate 514 a distance equal to the slot length, L_{S}. Accordingly, the offset mounting bracket 510 is a two-piece, adjustable component that provides an offset length measured between the first mounting tab 520 and the second mounting tab 522. The offset mounting bracket 510 is adjustable by sliding the second central plate 516 relative to the first central plate 514 and then, tightening a bolt, or fastener, that extends through the slot 542 and the bore 534 to maintain the position of the second central plate 516 relative to the first central plate 514. Accordingly, the offset mounting bracket 510 may include an offset length, L_{O}, that may be adjustable from L to 1.45 L.

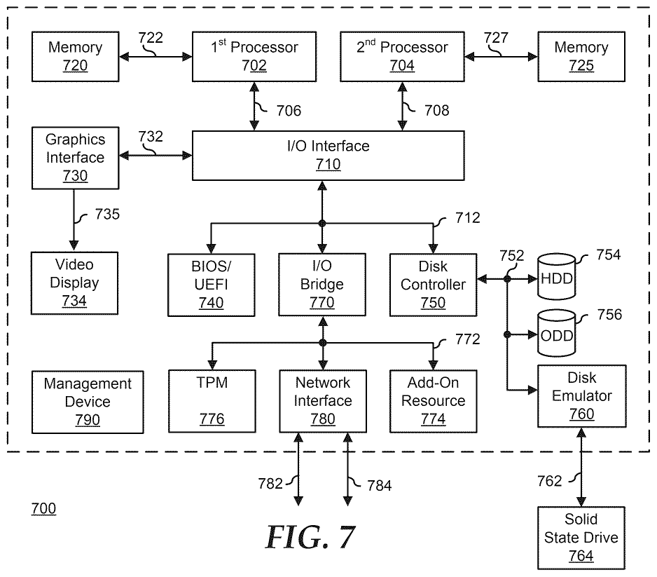

FIG. 7 shows a generalized embodiment of an information handling system 700 according to an embodiment of the present disclosure. Information handling system 700 may be substantially similar to the information handling system 104 of FIG. 1. For purpose of this disclosure an information handling system can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, information handling system 700 can be a personal computer, a laptop computer, a smart phone, a tablet device or other consumer electronic device, a network server, a network storage device, a switch router or other network communication device, or any other suitable device and may vary in size, shape, performance, functionality, and price. Further, information handling system 700 can include processing resources for executing machine-executable code, such as a central processing unit (CPU), a programmable logic array (PLA), an embedded device such as a System-on-a-Chip (SoC), or other control logic hardware. Information handling system 700 can also include one or more computer-readable medium for storing machine-executable code, such as software or data. Additional components of information handling system 700 can include one or more storage devices that can store machine-executable code, one or more communications ports for communicating with external devices, and various input and output (I/O) devices, such as a keyboard, a mouse, and a video display. Information handling system 700 can also include one or more buses operable to transmit information between the various hardware components.

Information handling system 700 can include devices or modules that embody one or more of the devices or modules described below and operates to perform one or more of the methods described herein. Information handling system 700 includes a processors 702 and 704, an input/output (I/O) interface 710, memories 720 and 725, a graphics interface 730, a basic input and output system/universal extensible firmware interface (BIOS/UEFI) module 740, a disk controller 750, a hard disk drive (HDD) 754, an optical disk drive (ODD) 756, a disk emulator 760 connected to an external solid state drive (SSD) 764, an I/O bridge 770, one or more add-on resources 774, a trusted platform module (TPM) 776, a network interface 780, a management device 790, and a power supply 795. Processors 702 and 704, I/O interface 710, memory 720, graphics interface 730, BIOS/UEFI module 740, disk controller 750, HDD 754, ODD 756, disk emulator 760, SSD 764, I/O bridge 770, add-on resources 774, TPM 776, and network interface 780 operate together to provide a host environment of information handling system 700 that operates to provide the data processing functionality of the information handling system. The host environment operates to execute machine-executable code, including platform BIOS/UEFI code, device firmware, operating system code, applications, programs, and the like, to perform the data processing tasks associated with information handling system 700.

In the host environment, processor 702 is connected to I/O interface 710 via processor interface 706, and processor 704 is connected to the I/O interface via processor interface 708. Memory 720 is connected to processor 702 via a memory interface 722. Memory 725 is connected to processor 704 via a memory interface 727. Graphics interface 730 is connected to I/O interface 710 via a graphics interface 732 and provides a video display output 736 to a video display 734. In a particular embodiment, information handling system 700 includes separate memories that are dedicated to each of processors 702 and 704 via separate memory interfaces. An example of memories 720 and 725 include random access memory (RAM) such as static RAM (SRAM), dynamic RAM (DRAM), non-volatile RAM (NV-RAM), or the like, read only memory (ROM), another type of memory, or a combination thereof.

BIOS/UEFI module 740, disk controller 750, and I/O bridge 770 are connected to I/O interface 710 via an I/O channel 712. An example of I/O channel 712 includes a Peripheral Component Interconnect (PCI) interface, a PCI-Extended (PCI-X) interface, a high-speed PCI-Express (PCIe) interface, another industry standard or proprietary communication interface, or a combination thereof. I/O interface 710 can also include one or more other I/O interfaces, including an Industry Standard Architecture (ISA) interface, a Small Computer Serial Interface (SCSI) interface, an Inter-Integrated Circuit (I²C) interface, a System Packet Interface (SPI), a Universal Serial Bus (USB), another interface, or a combination thereof. BIOS/UEFI module 740 includes BIOS/UEFI code operable to detect resources within information handling system 700, to provide drivers for the resources, initialize the resources, and access the resources. BIOS/UEFI module 740 includes code that operates to detect resources within information handling system 700, to provide drivers for the resources, to initialize the resources, and to access the resources.

Disk controller 750 includes a disk interface 752 that connects the disk controller to HDD 754, to ODD 756, and to disk emulator 760. An example of disk interface 752 includes an Integrated Drive Electronics (IDE) interface, an Advanced Technology Attachment (ATA) such as a parallel ATA (PATA) interface or a serial ATA (SATA) interface, a SCSI interface, a USB interface, a proprietary interface, or a combination thereof. Disk emulator 760 permits SSD 764 to be connected to information handling system 700 via an external interface 762. An example of external interface 762 includes a USB interface, an IEEE 7394 (Firewire) interface, a proprietary interface, or a combination thereof. Alternatively, solid-state drive 764 can be disposed within information handling system 700.

I/O bridge 770 includes a peripheral interface 772 that connects the I/O bridge to add-on resource 774, to TPM 776, and to network interface 780. Peripheral interface 772 can be the same type of interface as I/O channel 712 or can be a different type of interface. As such, I/O bridge 770 extends the capacity of I/O channel 712 when peripheral interface 772 and the I/O channel are of the same type, and the I/O bridge translates information from a format suitable to the I/O channel to a format suitable to the peripheral channel 772 when they are of a different type. Add-on resource 774 can include a data storage system, an additional graphics interface, a network interface card (NIC), a sound/video processing card, another add-on resource, or a combination thereof. Add-on resource 774 can be on a main circuit board, on separate circuit board or add-in card disposed within information handling system 700, a device that is external to the information handling system, or a combination thereof.

Network interface 780 represents a NIC disposed within information handling system 700, on a main circuit board of the information handling system, integrated onto another component such as I/O interface 710, in another suitable location, or a combination thereof. Network interface device 780 includes network channels 782 and 784 that provide interfaces to devices that are external to information handling system 700. In a particular embodiment, network channels 782 and 784 are of a different type than peripheral channel 772 and network interface 780 translates information from a format suitable to the peripheral channel to a format suitable to external devices. An example of network channels 782 and 784 includes InfiniBand channels, Fibre Channel channels, Gigabit Ethernet channels, proprietary channel architectures, or a combination thereof. Network channels 782 and 784 can be connected to external network resources (not illustrated). The network resource can include another information handling system, a data storage system, another network, a grid management system, another suitable resource, or a combination thereof.

Management device 790 represents one or more processing devices, such as a dedicated baseboard management controller (BMC) System-on-a-Chip (SoC) device, one or more associated memory devices, one or more network interface devices, a complex programmable logic device (CPLD), and the like, which operate together to provide the management environment for information handling system 700. In particular, management device 790 is connected to various components of the host environment via various internal communication interfaces, such as a Low Pin Count (LPC) interface, an Inter-Integrated-Circuit (I2C) interface, a PCIe interface, or the like, to provide an out-of-band (OOB) mechanism to retrieve information related to the operation of the host environment, to provide BIOS/UEFI or system firmware updates, to manage non-processing components of information handling system 700, such as system cooling fans and power supplies. Management device 790 can include a network connection to an external management system, and the management device can communicate with the management system to report status information for information handling system 700, to receive BIOS/UEFI or system firmware updates, or to perform other task for managing and controlling the operation of information handling system 700.

Management device 790 can operate off of a separate power plane from the components of the host environment so that the management device receives power to manage information handling system 700 when the information handling system is otherwise shut down. An example of management device 790 include a commercially available BMC product or other device that operates in accordance with an Intelligent Platform Management Initiative (IPMI) specification, a Web Services Management (WSMan) interface, a Redfish Application Programming Interface (API), another Distributed Management Task Force (DMTF), or other management standard, and can include an Integrated Dell Remote Access Controller (iDRAC), an Embedded Controller (EC), or the like. Management device 790 may further include associated memory devices, logic devices, security devices, or the like, as needed, or desired.

The systems and methods described herein may provide leak detection direct liquid cooled (DLC) systems that are non-invasive to various liquid cooled information handling systems and that are coolant agnostic because the typical coolants are mostly water. The UV dye, or UV pigment, only fluoresces when wet in the presence of UV radiation. The coating containing the UV dye or pigment may be applied to various component or system surfaces. As such, an optical leak detect system is provided that uses the fluorescence of the UV illuminated dye or pigment. One or more reflectors may be included to steer light. And, the reflectors may be shaped to tailor coverage for required area that is not within direct line of sight of the one or more optical leak sensors. The reflectors may be parts of shrouds or other existing plastic parts, covered by aluminum coated tape. Moreover, the reflectors may include holes, or apertures, to allow and promote cooling air flow.

Although only a few exemplary embodiments have been described in detail herein, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

What is claimed is:

1. A cabinet for an information handling system, comprising:
a housing;
a vertical adjustable mounting rail;
a horizontal information handling system support rail; and
an offset mounting bracket connecting the horizontal information handling system support rail to the vertical adjustable mounting rail, wherein the offset mounting bracket provides an offset length to move the horizontal information handling system support rail a distance away from the vertical adjustable mounting rail equal to the offset length.

2. The cabinet of claim 1, wherein the offset mounting bracket moves the horizontal information handling system support rail rearward relative to the vertical adjustable mounting rail.

3. The cabinet of claim 1, wherein the offset mounting bracket comprises:
a central portion;
a first mounting tab extending from the central portion in a first direction; and
a second mounting tab extending from the central portion in a second direction.

4. The cabinet of claim 3, wherein the first mounting tab includes an indexing post extending therefrom and at least one bore extending therethrough, the second mounting tab includes at least one bore extending therethrough, and the central portion includes a bore extending therethrough.

5. The cabinet of claim 4, wherein the offset mounting bracket is a one-piece, monolithic component.

6. The cabinet of claim 5, wherein the central portion is a central plate and the first mounting tab and the second mounting tab extend from the central plate.

7. The cabinet of claim 4, wherein the offset mounting bracket is a two-piece adjustable component.

8. The cabinet of claim 7, wherein the central portion of the offset mounting bracket includes a first central plate and a second central plate slidably engaged therewith.

9. The cabinet of claim 8, wherein the first mounting tab extends from the first central plate and the second mounting tab extends from the second central plate.

10. The cabinet of claim 9, wherein the first central plate includes a bore and the second central plate includes a slot aligned with the bore.

11. A cabinet for an information handling system, comprising:
a housing;
a vertical adjustable mounting rail;
a horizontal information handling system support rail; and
an offset mounting bracket connecting the horizontal information handling system support rail to the vertical adjustable mounting rail, wherein the offset mounting bracket comprises:
a central plate;
a first mounting tab, wherein the first mounting tab extends from the central plate in a first direction; and
a second mounting tab, wherein the second mounting tab extends from the central plate in a second direction.

12. The cabinet of claim 11, wherein the offset mounting bracket provides an offset length to move the horizontal information handling system support rail a distance away from the vertical adjustable mounting rail equal to the offset length.

13. The cabinet of claim 12, wherein the first mounting tab includes an indexing post extending therefrom and at least one bore extending therethrough.

14. The cabinet of claim 13, the second mounting tab includes at least one bore extending therethrough and the central plate includes a bore extending therethrough.

15. The cabinet of claim 14, wherein the offset mounting bracket is a one-piece, monolithic component.

16. A cabinet for an information handling system, comprising:
a housing;
a vertical adjustable mounting rail;
a horizontal information handling system support rail; and
an offset mounting bracket connecting the horizontal information handling system support rail to the vertical adjustable mounting rail, wherein the offset mounting bracket comprises:
a first central plate;
a second central plate slidable relative to the first central plate;
a first mounting tab, wherein the first mounting tab extends from the central plate in a first direction; and
a second mounting tab, wherein the second mounting tab extends from the central plate in a second direction.

17. The cabinet of claim 16, wherein the offset mounting bracket provides an adjustable offset length to move the horizontal information handling system support rail one or more distances away from the vertical adjustable mounting rail equal to the adjustable offset length.

18. The cabinet of claim 17, wherein the first mounting tab includes an indexing post extending therefrom and at least one bore extending therethrough.

19. The cabinet of claim 18, the second mounting tab includes at least one bore extending therethrough and the central plate includes a bore extending therethrough.

20. The cabinet of claim 9, wherein the first central plate includes a bore and the second central plate includes a slot aligned with the bore.
